(19) United States
(12) Patent Application Publication
(10) Pub. No.: US 2025/0038093 A1
(43) Pub. Date: Jan. 30, 2025

(54) INTERPOSERS INCLUDING LINE-ON-VIA AND LINE-IN-VIA INTERCONNECT STRUCTURES AND METHODS OF FORMING THE SAME

(71) Applicant: Taiwan Semiconductor Manufacturing Company Limited, Hsinchu (TW)

(72) Inventors: Monsen Liu, Hsinchu (TW); Hsin-Yu Chen, Taipei City (TW); Shuo-Mao Chen, New Taipei City (TW); Chia-Hsiang Lin, Zhubei City (TW); Shin-Puu Jeng, Po-Shan Village (TW)

(21) Appl. No.: 18/360,354

(22) Filed: Jul. 27, 2023

(51) Int. Cl. H01L 23/498; H01L 21/48

(52) U.S. Cl. CPC H01L 23/49838; H01L 21/4857; H01L 23/49822

(57) ABSTRACT

An embodiment interposer includes a first electrically conducting line structure, an electrically conducting via structure that is electrically connected to the first electrically conducting line structure, and a second electrically conducting line structure formed along with the electrically conducting via structure as a monolithic structure. In some embodiments, a portion of the first electrically conducting line structure may be provided within the electrically conducting via structure such that the first electrically conducting line structure is at least partially overlapping with the electrically conducting via structure such that the first electrically conducting line structure and the electrically conducting via structure share a common surface. In other embodiments, the interposer may further include a via land structure electrically connected to the first electrically conducting line structure. In some embodiments, the via land structure may have an elongated structure having a land width that is smaller than a land length.

### BACKGROUND

Semiconductor devices are used in a variety of electronic applications, such as personal computers, cell phones, digital cameras, and other electronic equipment. Semiconductor devices are typically fabricated by sequentially depositing insulating or dielectric layers, conductive layers, and semiconductive layers of material over a semiconductor substrate, and patterning the various material layers using lithography to form circuit components and elements thereon. Dozens or hundreds or thousands of integrated circuits are typically manufactured on a single semiconductor wafer, and individual dies on the wafer are singulated by sawing between the integrated circuits along scribe lines. The individual dies are typically packaged separately, in multi-chip modules, or in other types of packaging, for example.

In addition to the improvements that form smaller electronic components, improvements to the packaging of components have been developed in an effort to provide smaller packages that occupy less area than previous packages. Example approaches include quad flat pack (QFP), pin grid array (PGA), ball grid array (BGA), flip chips (FC), 3-dimensional integrated circuits (3DICs), wafer level packages (WLPs), package on package (POP), System on Chip (SoC) or System on Integrated Circuit (SoIC) devices. Some of these 3-dimensional devices (e.g., 3DIC, SoC, SoIC) are prepared by placing chips over chips on a semiconductor wafer level. These 3-dimensional devices provide improved integration density and other advantages, such as faster speeds and higher bandwidth, because of the decreased length of interconnects between the stacked chips. However, there are many challenges related to 3-dimensional devices.

### BRIEF DESCRIPTION OF THE DRAWINGS

Aspects of this disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is vertical cross-sectional exploded view of components of a related semiconductor package during a package assembly and surface mounting process.

FIG. 1B is a vertical cross-sectional view illustrating a related assembled semiconductor package mounted onto the surface of a support substrate.

FIG. 2 is a vertical cross-sectional view of a portion of an interposer having a increased interconnect density, according to various embodiments.

FIG. 3A is a first vertical cross-sectional view of a portion of a further interposer having a increased interconnect density, according to various embodiments.

FIG. 3B is a second vertical cross-sectional view of the portion of the interposer of FIG. 3A, according to various embodiments.

FIG. 3C is a top view of an electrical interconnect structure of the interposer of FIG. 3A, according to various embodiments.

FIG. 3D is a bottom view of the electrical interconnect structure of FIG. 3C, according to various embodiments.

FIG. 3E is a three-dimensional top perspective view of the electrical interconnect structure of FIG. 3C, according to various embodiments.

FIG. 3F is a three-dimensional bottom perspective view of the electrical interconnect structure of the interposer of FIG. 3D, according to various embodiments.

FIG. 4A is vertical cross-sectional view of an intermediate structure that may be used in the formation of an interposer, according to various embodiments.

FIG. 4B is vertical cross-sectional view of a further intermediate structure that may be used in the formation of an interposer, according to various embodiments.

FIG. 4C is vertical cross-sectional view of a further intermediate structure that may be used in the formation of an interposer, according to various embodiments.

FIG. 4D is vertical cross-sectional view of a further intermediate structure that may be used in the formation of an interposer, according to various embodiments.

FIG. 4E is vertical cross-sectional view of a further intermediate structure that may be used in the formation of an interposer, according to various embodiments.

FIG. 4F is vertical cross-sectional view of a further intermediate structure that may be used in the formation of an interposer, according to various embodiments.

FIG. 4G is vertical cross-sectional view of a further intermediate structure that may be used in the formation of an interposer, according to various embodiments.

FIG. 4H is vertical cross-sectional view of a further intermediate structure that may be used in the formation of an interposer, according to various embodiments.

FIG. 5A is vertical cross-sectional view of an intermediate structure that may be used in the formation of a further interposer, according to various embodiments.

FIG. 5B is vertical cross-sectional view of a further intermediate structure that may be used in the formation of an interposer, according to various embodiments.

FIG. 5C is vertical cross-sectional view of a further intermediate structure that may be used in the formation of an interposer, according to various embodiments.

FIG. 5D is vertical cross-sectional view of a further intermediate structure that may be used in the formation of an interposer, according to various embodiments.

FIG. 5E is vertical cross-sectional view of a further intermediate structure that may be used in the formation of an interposer, according to various embodiments.

FIG. 5F is vertical cross-sectional view of a further intermediate structure that may be used in the formation of an interposer, according to various embodiments.

FIG. 5G is vertical cross-sectional view of a further intermediate structure that may be used in the formation of an interposer, according to various embodiments.

FIG. 5H is vertical cross-sectional view of a further intermediate structure that may be used in the formation of an interposer, according to various embodiments.

FIG. 5I is vertical cross-sectional view of a further intermediate structure that may be used in the formation of an interposer, according to various embodiments.

FIG. 6A is a first vertical cross-sectional view of a portion of a further interposer having a increased interconnect density, according to various embodiments.

FIG. 6B is a second vertical cross-sectional view of the portion of the interposer of FIG. 6A, according to various embodiments.

FIG. 6C is a top view of electrical interconnect structures of the portion of the interposer of FIGS. 6A and 6B, according to various embodiments.

FIG. 6D is a horizontal cross-sectional view of the portion of the interposer of FIGS. 6A and 6B, according to various embodiments.

FIG. 7A is vertical cross-sectional view of an intermediate structure that may be used in the formation of a further interposer, according to various embodiments.

FIG. 7B is vertical cross-sectional view of a further intermediate structure that may be used in the formation of an interposer, according to various embodiments.

FIG. 7C is vertical cross-sectional view of a further intermediate structure that may be used in the formation of an interposer, according to various embodiments.

FIG. 7D is vertical cross-sectional view of a further intermediate structure that may be used in the formation of an interposer, according to various embodiments.

FIG. 7E is vertical cross-sectional view of a further intermediate structure that may be used in the formation of an interposer, according to various embodiments.

FIG. 7F is vertical cross-sectional view of a further intermediate structure that may be used in the formation of an interposer, according to various embodiments.

FIG. 7G is vertical cross-sectional view of a further intermediate structure that may be used in the formation of an interposer, according to various embodiments.

FIG. 7H is vertical cross-sectional view of a further intermediate structure that may be used in the formation of an interposer, according to various embodiments.

FIG. 8 is a flowchart of a method of forming an interposer, according to various embodiments.

### DETAILED DESCRIPTION

The following disclosure provides many different embodiments, or examples, for implementing different features of the provided subject matter. Specific examples of components and arrangements are described below to simplify this disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, this disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Unless explicitly stated otherwise, each element having the same reference numeral is presumed to have the same material composition and to have a thickness within a same thickness range.

Typically, in a semiconductor package, a number of semiconductor integrated circuit (IC) dies (i.e., “chips”) may be mounted onto a common substrate, which may also be referred to as a “package substrate.” In some embodiments, electrical connections to the semiconductor package may be made by mounting the package substrate onto a support substrate containing electrical interconnects, such as a printed circuit board (PCB). A semiconductor package may further include an interposer to which one or more semiconductor dies are attached and electrically coupled. The interposer, in turn, may be attached and electrically coupled to a package substrate, which may be further attached to a PCB. As such, separate structures (e.g., semiconductor dies, interposer, package substrate, and PCB) may be fabricated and then assembled.

A disclosed interposer may be advantageous by providing electrical interconnect structures having an increased interconnect density relative to comparative interposers. In this regard, in certain embodiments, an interposer may include a first electrically conducting line structure and an electrically conducting via structure formed over the first electrically conducting line structure such that the electrically conducting via structure is electrically connected to, and partially surrounds, a portion of the first electrically conducting line structure. In this way, a portion of the first electrically conducting line structure is protruding within the electrically conducting via structure so as to overlap with the electrically conducting via structure. As such, a combined spatial extent of the first electrically conducting line structure and the electrically conducting via structure along a thickness direction may be equal to the via thickness, and a combined spatial extent of the first electrically conducting line structure and the electrically conducting via structure along a width direction may be equal to the via width. In this way, a vertical density and a horizontal density of interconnect structures may be increased relative to comparative interposers that do not include overlapping line and via structures.

An embodiment interposer may include a first electrically conducting line structure and an electrically conducting via structure that is electrically connected to the first electrically conducting line structure, such that a portion of the first electrically conducting line structure protrudes into the electrically conducting via structure so as to be overlapping with the electrically conducting via structure. A first line thickness of the first electrically conducting line structure may be less than a via thickness of the electrically conducting via structure such that the first electrically conducting line structure is at least partially overlapping with the electrically conducting via structure along a thickness direction. Similarly, a first line width of the first electrically conducting line structure may be less than a via width of the electrically conducting via structure such that the first electrically conducting line structure is at least partially overlapping with the electrically conducting via structure along a width direction.

Another embodiment interposer includes a first electrically conducting line structure, an electrically conducting via structure that is electrically connected to the first electrically conducting line structure, and a second electrically conducting line structure formed along with the electrically conducting via structure as a monolithic structure. In some embodiments, a portion of the first electrically conducting line structure may be provided within the electrically conducting via structure such that the first electrically conducting line structure is at least partially overlapping with the electrically conducting via structure such that the first electrically conducting line structure and the electrically conducting via structure share a common surface. In other embodiments, the interposer may further include a via land structure electrically connected to the first electrically conducting line structure. In some embodiments, the via land structure may have an elongated structure having a land width that is smaller than a land length.

A further embodiment interposer may include a first dielectric layer, a second dielectric layer formed over the first dielectric layer, a first electrically conducting line structure formed over the first dielectric layer and within the second dielectric layer, and an electrically conducting via structure formed within the second dielectric layer and formed over the first electrically conducting line structure such that the electrically conducting via structure is electrically connected to, and partially surrounds, a portion of the first electrically conducting line structure. A first line thickness of the first electrically conducting line structure may be less than a via thickness of the electrically conducting via structure such that a combined spatial extent of the first electrically conducting line structure and the electrically conducting via structure along a thickness direction is equal to the via thickness. Similarly, a first line width of the first electrically conducting line structure may be less than a via width of the electrically conducting via structure such that a combined spatial extent of the first electrically conducting line structure and the electrically conducting via along a width direction is equal to the via width.

A further embodiment interposer may include a first dielectric layer, a second dielectric layer formed over the first dielectric layer, a first electrically conducting line structure formed over the first dielectric layer and within the second dielectric layer, an electrically conducting via structure formed within the second dielectric layer, and a second electrically conducting line structure formed along with the electrically conducting via structure as a monolithic structure. In some embodiments, the electrically conducting via structure may be formed within the second dielectric layer and formed over the first electrically conducting line structure such that the electrically conducting via structure is electrically connected to, and partially surrounds, a portion of the first electrically conducting line structure. In other embodiments, the interposer may further include a via land structure electrically connected to the first electrically conducting line structure. In some embodiments, the via land structure may have an elongated structure having a land width that is smaller than a land length.

An embodiment method of forming an interposer may include forming a first electrically conducting line structure over a first dielectric layer; forming a second dielectric layer over the first electrically conducting line structure; and forming an electrically conducting via structure within the second dielectric layer and over the first electrically conducting line structure such that an electrical connection is formed between the first electrically conducting line structure and the electrically conducting via structure. The method may include forming the first electrically conducting line structure such that a first line thickness of the first electrically conducting line structure is less than a via thickness of the electrically conducting via structure so that a combined spatial extent of the first electrically conducting line structure and the electrically conducting via along a thickness direction is equal to the via thickness.

Another embodiment method of forming an interposer may include forming a first electrically conducting line structure over a first dielectric layer, forming a second dielectric layer over the first electrically conducting line structure, forming an electrically conducting via structure within the second dielectric layer such that an electrical connection is formed between the first electrically conducting line structure and the electrically conducting via structure, and forming a second electrically conducting line structure along with the electrically conducting via structure as a monolithic structure. In some embodiments, the method may include forming the electrically conducting via structure over the first electrically conducting line structure such that the electrically conducting via structure is electrically connected to, and partially surrounds, a portion of the first electrically conducting line structure. In other embodiments, the method may include forming a via land structure electrically connected to the first electrically conducting line structure such that the via land structure has an elongated structure having a land width that is smaller than a land length.

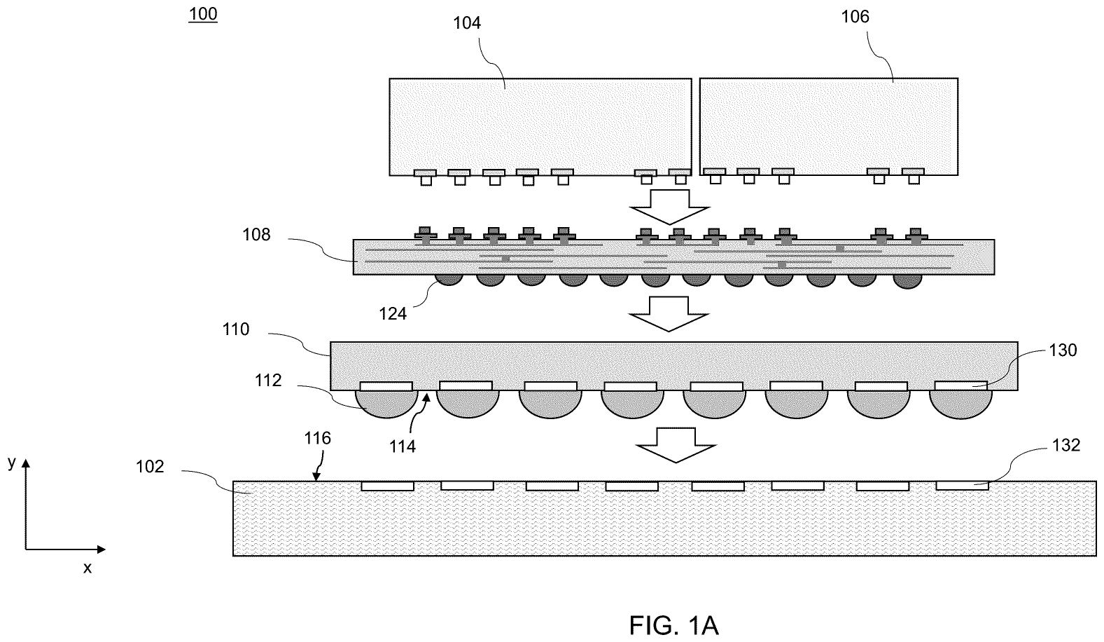

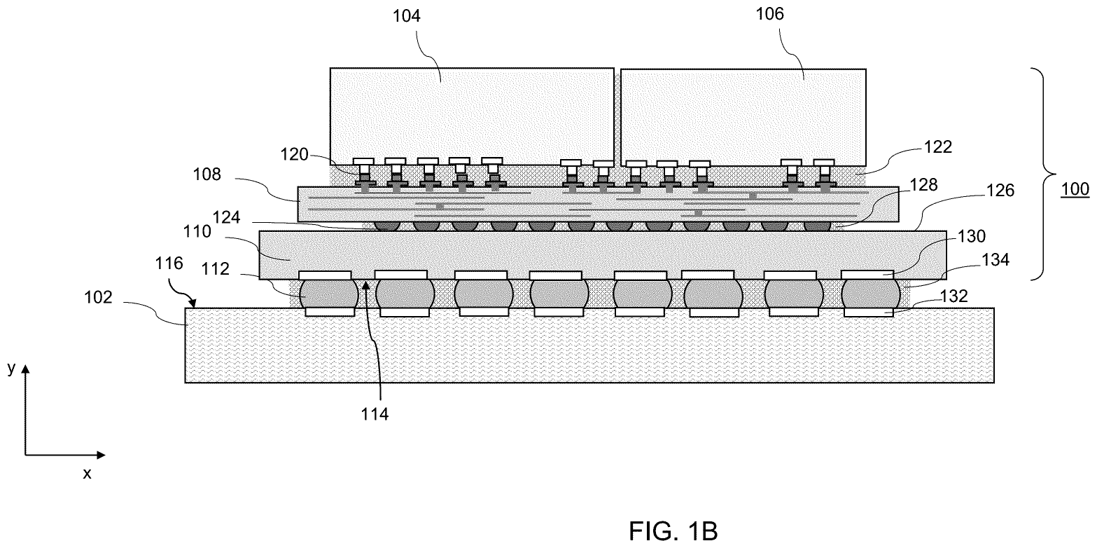

FIG. 1A is vertical cross-section exploded view of components of a related semiconductor package 100 during a package assembly and surface mounting process. FIG. 1B is a vertical cross-section view illustrating the related assembled semiconductor package 100 mounted onto the surface of a support substrate 102, such as a printed circuit board (PCB). The semiconductor package 100 is merely an example type of semiconductor package, although it will be understood that a similar assembly and mounting process may be utilized for other types of semiconductor packages.

Referring to FIGS. 1A and 1B, the related semiconductor package 100 may include integrated circuit (IC) semiconductor devices, such as first semiconductor devices 104 and second semiconductor devices 106. During the package assembly process, the first semiconductor device 104 and the second semiconductor device 106 may be mounted on an interposer 108, and the interposer 108 containing the first semiconductor device 104 and the second semiconductor device 106 may be mounted onto a package substrate 110 to form a semiconductor package 100. The semiconductor package 100 may then be mounted to a support substrate 102, such as a printed circuit board (PCB), by mounting the package substrate 110 to the support substrate 102 using an array of first solder balls 112 on the lower surface 114 of the package substrate 110.

A parameter that may ensure proper interconnection between the package substrate 110 and the support substrate 102 is the degree of co-planarity between the surfaces of the first solder balls 112 that may be brought into contact with the mounting surface (i.e., the upper surface 116 of the support substrate 102 in FIG. 1A). A low degree of co-planarity between the first solder balls 112 may result in instances of solder cold joints (i.e., insufficient melting of the solder material, resulting in a poor bond that is susceptible to cracking and separation) and/or solder bridging issues (i.e., solder material from one solder ball 112 contacting material from a neighboring solder ball 112, resulting in an unintended connection (i.e., electrical short)) during the reflow process.

Deformation of the package substrate 110, such as stress-induced warping of the package substrate 110, may be a contributor to low co-planarity of the first solder balls 112 during surface mounting of the package substrate 110 onto a support substrate 102. Deformation of the package substrate 110 is not an uncommon occurrence, particularly in the case of semiconductor packages 100 used in high-performance computing applications. These high-performance semiconductor packages 100 tend to be relatively large and may include a number of semiconductor devices (e.g., 104, 106) mounted to the package substrate 110, which may increase a likelihood that the package substrate 110 may be subject to warping or other deformations. Such deformations may present challenges to effective solder mounting of these types of semiconductor package substrates 110 onto a support substrate 102.

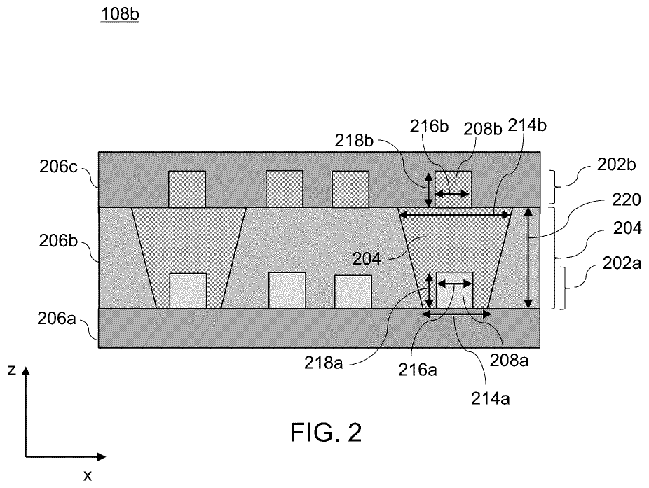

Various disclosed embodiments may include semiconductor devices having redistribution layers formed directly on an active wafer or semiconductor die, as described in greater detail (e.g., see FIG. 2), below. Such structures may be configured to be attached directly to the package substrate 110 without the need for a separate interposer 108. As such, embodiment structures may be more modular, simpler to fabricate, and may have fewer issues related to stress-induced warping of the package substrate 110, as described in greater detail, below.

In various embodiments, the first semiconductor devices 104 may be three-dimensional devices, such as three-dimensional integrated circuits (3DICs), System on Chip (SOC) or System on Integrated Circuit (SoIC) devices. A three-dimensional semiconductor device 104 may be formed by placing chips over chips on a semiconductor wafer level. These three-dimensional devices may provide improved integration density and other advantages, such as faster speeds and higher bandwidths, due to a decreased length of interconnects between the stacked chips. In some embodiments, a first three-dimensional semiconductor device 104 may also be referred to as a “first die stack.”

The second semiconductor device(s) 106 may be different from the first semiconductor device(s) 104 in terms of their structure, design and/or functionality. The one or more second semiconductor devices 106 may be three-dimensional semiconductor devices, which may also be referred to as “second die stacks.” In some embodiments, the one or more second semiconductor devices 106 may include a memory device, such as a high bandwidth memory (HBM) device. In the example shown in FIGS. 1A and 1B, the semiconductor package 100 may include a SOC die stack 104 and an HBM die stack 106, although it will be understood that the semiconductor package 100 may include greater or fewer numbers of semiconductor devices.

Referring again to FIG. 1B, the first semiconductor devices 104 and second semiconductor devices 106 may be mounted on an interposer 108. In some instances, the interposer 108 may be an organic interposer including a polymer dielectric material (e.g., a polyimide material) having a plurality of metal interconnect structures extending therethrough. In other instances, the interposer 108 may be a semiconductor interposer, such as a silicon interposer, having a plurality of interconnect structures (e.g., through-silicon vias) extending therethrough. Other suitable configurations for the interposer 108 are within the contemplated scope of the disclosure. The interposer 108 may include a plurality of conductive bonding pads on upper and lower surfaces of the interposer and a plurality of conductive interconnects extending through the interposer 108 between the upper and lower bonding pads of the interposer 108. The conductive interconnects may distribute and route electrical signals between the first semiconductor devices 104, the second semiconductor devices 106, and the underlying package substrate 110. Thus, the interposer 108 may also be referred to as a redistribution layer (RDL).

A plurality of first metal bumps 120, such as microbumps, may electrically connect conductive bonding pads on the bottom surfaces of the first semiconductor devices 104 and second semiconductor devices 106 to the conductive bonding pads on the upper surface of the interposer 108. In one non-limiting embodiment, first metal bumps 120 in the form of microbumps may include a plurality of first metal stacks, such as a plurality of Cu—Ni—Cu stacks, located on the bottom surfaces of the first semiconductor devices 104 and second semiconductor devices 106, and a plurality of second metal stacks (e.g., Cu—Ni—Cu stacks) located on the upper surface of the interposer 108. A solder material, such as tin (Sn), may be located between respective first and second metal stacks to electrically connect the first semiconductor devices 104 and the second semiconductor devices 106 to the interposer 108. Other suitable materials for the first metal bumps 120 are within the contemplated scope of disclosure.

After the first semiconductor devices 104 and second semiconductor devices 106 are mounted to the interposer 108, a first underfill material portion 122 may optionally be provided in the spaces surrounding the first metal bumps 120 and between the bottom surfaces of the first semiconductor devices 104, the second semiconductor devices 106, and the upper surface of the interposer 108 as shown in FIG. 1B. The first underfill material portion 122 may also be provided in the spaces laterally separating adjacent first semiconductor devices 104 and second semiconductor devices 106 of the semiconductor package 100. In various embodiments, the first underfill material portion 122 may include of an epoxy-based material, which may include a composite of resin and filler materials.

Referring again to FIG. 1B, the interposer 108 may be mounted on the package substrate 110 that may provide mechanical support for the interposer 108 and the first semiconductor devices 104 and second semiconductor devices 106 that are mounted on the interposer 108. The package substrate 110 may include a suitable material, such as an organic material (e.g., a polymer and/or thermoplastic material), a semiconductor material (e.g., a semiconductor wafer, such as a silicon wafer), a ceramic material, a glass material, combinations thereof, etc. Other suitable substrate materials are within the contemplated scope of present disclosure. In various embodiments, the package substrate 110 may include a plurality of conductive bonding pads (not shown) in an upper surface 126 of the package substrate 110. A plurality of second metal bumps 124, such as C4 solder bumps, may electrically connect conductive bonding pads (not shown) on the bottom surface of the interposer 108 to the conductive bonding pads on the upper surface 126 of the package substrate 110. In various embodiments, the second metal bumps 124 may include a suitable solder material, such as tin (Sn), although other suitable solder materials are within the contemplated scope of disclosure.

A second underfill material portion 128 may be provided in the spaces surrounding the second metal bumps 124 and between the bottom surface of the interposer 108 and the upper surface 126 of the package substrate 110 as illustrated, for example, in FIG. 1B. In various embodiments, the second underfill material portion 128 may include an epoxy-based material, which may include a composite of resin and filler materials. In some embodiments, a lid or cover (not shown in FIGS. 1A and 1B) may be mounted to the package substrate 110 and may provide an enclosure around the upper and side surfaces of the first semiconductor devices 104 and second semiconductor devices 106.

As described above, the package substrate 110 may be mounted to the support substrate 102, such as a printed circuit board (PCB). Other suitable support substrates 102 are within the contemplated scope of disclosure. The package substrate 110 may include a plurality of conductive bonding pads 130 in a lower surface 114 of the package substrate 110. A plurality of conductive interconnects (not shown) may extend through the package substrate 110 between conductive bonding pads on the upper surface 126 and lower surface 114 of the package substrate 110. The plurality of first solder balls 112 (or bump structures) may electrically connect the conductive bonding pads 130 on the lower surface 114 of the package substrate 110 to a plurality of conductive bonding pads 132 on the upper surface 116 of the support substrate 102.

The bonding pads 130 of the package substrate 110 and bonding pads 132 of the support substrate 102 may be formed of a suitable conductive material, such as copper. Other suitable conductive materials are within the contemplated scope of disclosure. The plurality of first solder balls 112 on the lower surface 114 of the package substrate 110 may form an array of first solder balls 112, such as a ball grid array (BGA) that may include an array pattern that corresponds to an array pattern of the conductive bonding pads 132 on the upper surface 116 of the support substrate 102. In one non-limiting example, the array of first solder balls 112 may include a grid pattern and may have a pitch (i.e., distance between the center of each solder ball 112 and the center of each adjacent solder ball 112). In an example embodiment, the pitch may be between about 0.8 and 1.0 mm, although larger and smaller pitches may be used. The first solder balls 112 may include any suitable solder material, such as tin, lead, silver, indium, zinc, nickel, bismuth, antimony, cobalt, copper, germanium, alloys thereof, combinations thereof, or the like. Other suitable materials for the first solder balls 112 are within the contemplated scope of disclosure.

In some embodiments, the lower surface 114 of the package substrate 110 may include a coating of solder resist (SR) material (not shown), which may also be referred to as a “solder mask”. A SR material coating may provide a protective coating for the package substrate 110 and any underlying circuit patterns formed on or within the package substrate 110. An SR material coating may also inhibit solder material from adhering to the lower surface 114 of the package substrate 110 during a reflow process. In embodiments in which the lower surface 114 of the package substrate 110 includes an SR coating, the SR material coating may include a plurality of openings through which the bonding pads 130 may be exposed.

In various embodiments, each of the conductive bonding pads 130 in different regions of the package substrate 110 may have the same size and shape. In the embodiment shown in FIGS. 1A and 1B, the surfaces of the bonding pads 130 may be substantially co-planar with the lower surface 114 of the package substrate 110, which in some embodiments may include a solder resist (SR) coating. Alternatively, the surfaces of the bonding pads 130 may be recessed relative to the lower surface 114 of the package substrate 110. In some embodiments, the surfaces of the bonding pads 130 may be raised relative to the lower surface 114 of the package substrate 110.

Referring again to FIGS. 1A and 1B, first solder balls 112 may be provided over the respective conductive bonding pads 130. In one non-limiting example, the conductive bonding pads 130 may have a width dimension that is between about 500 μm and about 550 μm (e.g., ˜530 μm), and the first solder balls 112 may have an outer diameter that may be between about 600 μm and about 650 μm (e.g., ˜630 μm), although greater and smaller sizes of the first solder balls 112 and/or the bonding pads 130 are within the contemplated scope of disclosure.

A first solder reflow process may include subjecting the package substrate 110 to an elevated temperature (e.g., at least about 250° C.) in order to melt the first solder balls 112 and to cause the first solder balls 112 to adhere to the conductive bonding pads 130. Following the first reflow process, the package substrate 110 may be cooled causing the first solder balls 112 to re-solidify. Following the first solder reflow process, the first solder balls 112 may adhere to the conductive bonding pads 130. Each solder ball 112 may extend from the lower surface 114 of the package substrate 110 by a vertical height that may be less than the outer diameter of the solder ball 112 prior to the first reflow process. For example, where the outer diameter of the solder ball 112 is between about 600 μm and about 650 μm (e.g., ˜630 μm), the vertical height of the solder ball 112 following the first reflow process may be between about 500 μm and about 550 μm (e.g., ˜520 μm).

In various embodiments, the process of mounting the package substrate 110 onto the support substrate 102 as shown in FIG. 1B, may include aligning the package substrate 110 over the support substrate 102, such that the first solder balls 112 contacting the conductive bonding pads 130 of the package substrate 110 may be located over corresponding bonding pads (e.g., bonding pads 132) on the support substrate 102. A second solder reflow process may then be performed. The second solder reflow process may include subjecting the package substrate 110 to an elevated temperature (e.g., at least about 250° C.) to thereby melt the first solder balls 112 and cause the first solder balls 112 to adhere to the corresponding bonding pads 132 on the support substrate 102. Surface tension may cause the semi-liquid solder to maintain the package substrate 110 in alignment with the support substrate 102 while the solder material cools and solidifies. Upon solidification of the first solder balls 112, the package substrate 110 may sit above the upper surface 116 of the support substrate 102 by a stand-off height that may be between about 0.4 mm to about 0.5 mm, although greater or lesser stand-of heights are within the contemplated scope of disclosure.

Following the mounting of the package substrate 110 to the support substrate 102, a third underfill material portion 134 may be provided in the spaces surrounding the first solder balls 112 and between the lower surface 114 of the package substrate 110 and the upper surface 116 of the support substrate 102, as is shown in FIG. 1B. In various embodiments, the third underfill material portion 134 may include an epoxy-based material, which may include a composite of resin and filler materials.

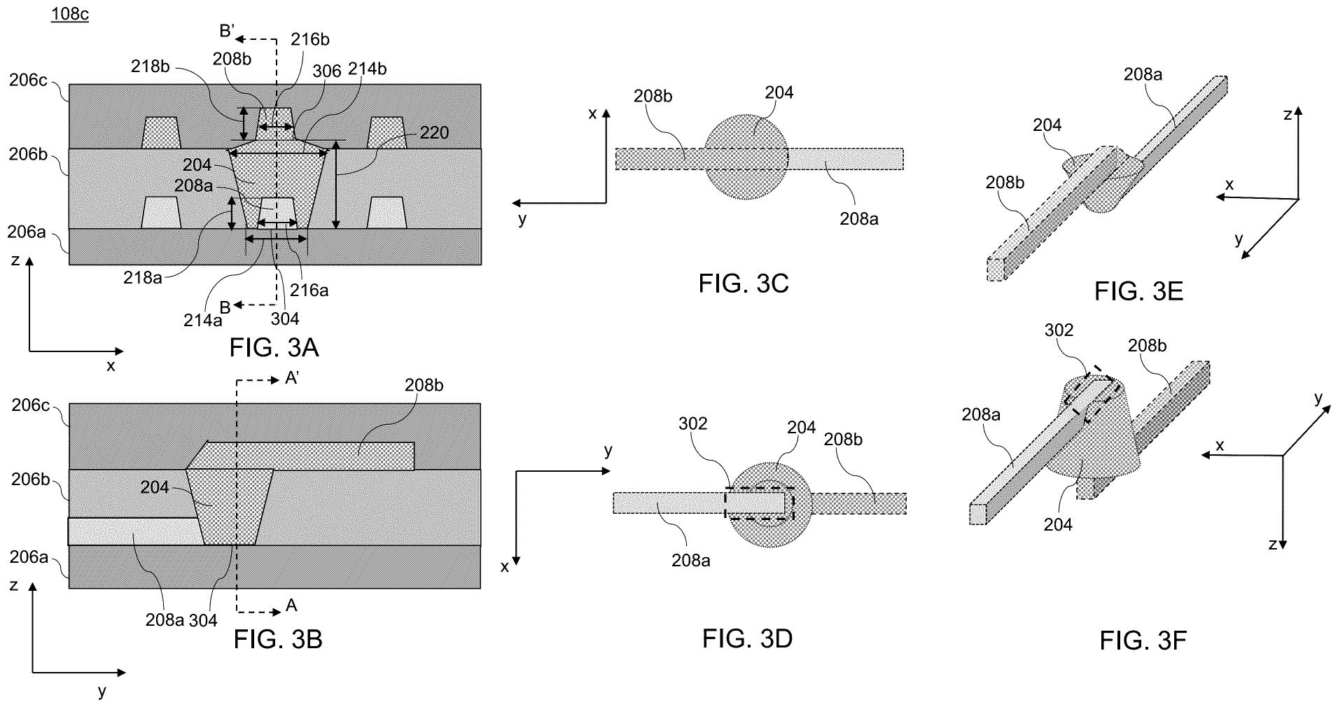

FIG. 2 is a vertical cross-sectional view of a portion of an interposer 108b having an increased interconnect density, according to various embodiments. As shown, the interposer 108b may include a first dielectric layer 206a, a second dielectric layer 206b formed over the first dielectric layer 206a, and a first electrically conducting line structure 208a formed over the first dielectric layer 206a and within the second dielectric layer 206b. The interposer 108b may further include an electrically conducting via structure 204 formed within the second dielectric layer 206b and formed over the first electrically conducting line structure 208a such that the electrically conducting via structure 204 is electrically connected to, and partially surrounds, a portion of the first electrically conducting line structure 208a, as described in greater detail with reference to FIGS. 3A to 3F, below. As shown in FIG. 2, the first electrically conducting line structure 208a and the electrically conducting via structure 204 form a “line-in-via” structure.

As shown in FIG. 2, a first line thickness 218a of the first electrically conducting line structure 208a may be less than a via thickness 220 of the electrically conducting via structure 204 such that a combined spatial extent of the first electrically conducting line structure 208a and the electrically conducting via structure along a thickness direction (i.e., the z-direction in FIG. 2) is equal to the via thickness 220. In this way, a vertical density of electrical interconnect structures may be increased relative to embodiments in which the first electrically conducting line structure 208a does not spatially overlap with the electrically conducting via structure 204 (not shown). The overall thickness of the via 204 and electrically conducting line structure 208a may correspond to that of the thickness of the electrically conducting via structure 204 alone. Similarly, a first line width 216a of the first electrically conducting line structure 208a may be less than a via width (214a, 214b) of the electrically conducting via structure 204 such that a combined spatial extent of the first electrically conducting line structure 208a and the electrically conducting via structure 204 along a width direction (i.e., along the x-direction in FIG. 2) is equal to the via width (214a, 214b). As such, a horizontal density of electrical interconnect structures may be increased relative to embodiments in which the first electrically conducting line structure 208a does not spatially overlap with the electrically conducting via structure 204 (not shown).

The interposer 108b may further include a third dielectric layer 206c formed over the second dielectric layer 206b and a second electrically conducting line structure 208b formed over the second dielectric layer 206b and within the third dielectric layer 206c. The second electrically conducting line structure 208b may be further electrically connected to the electrically conducting via structure 204. As shown in FIG. 2, the second electrically conducting line structure 208b and the electrically conducting via structure 204 form a “line-on-via” structure.

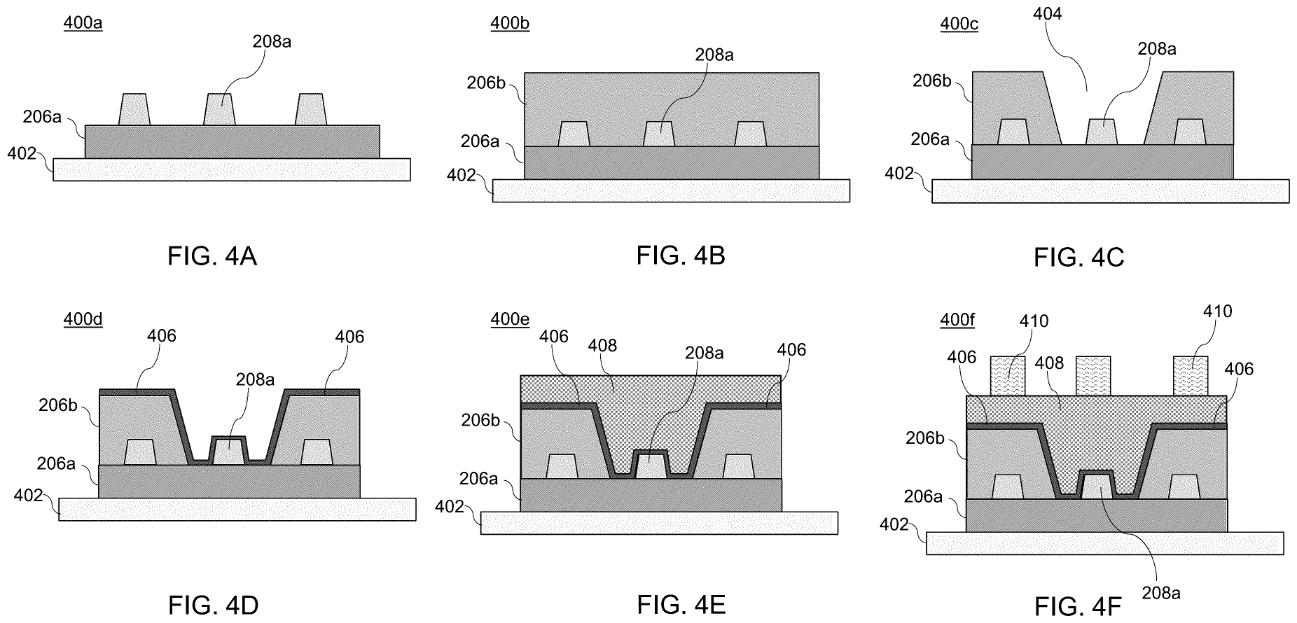

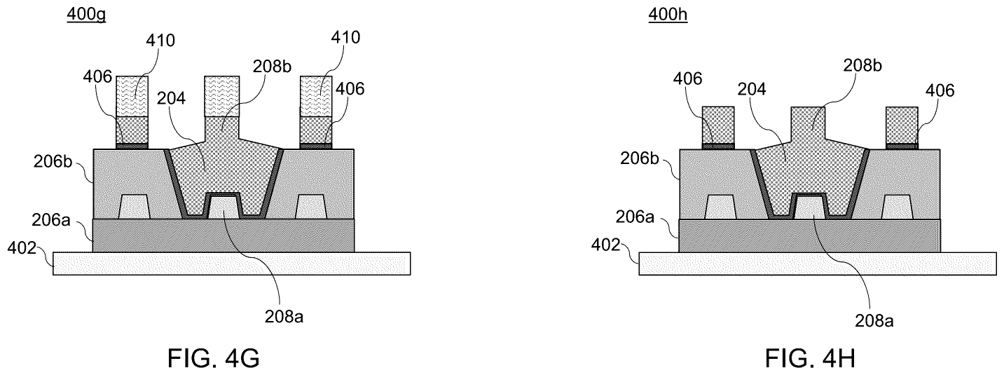

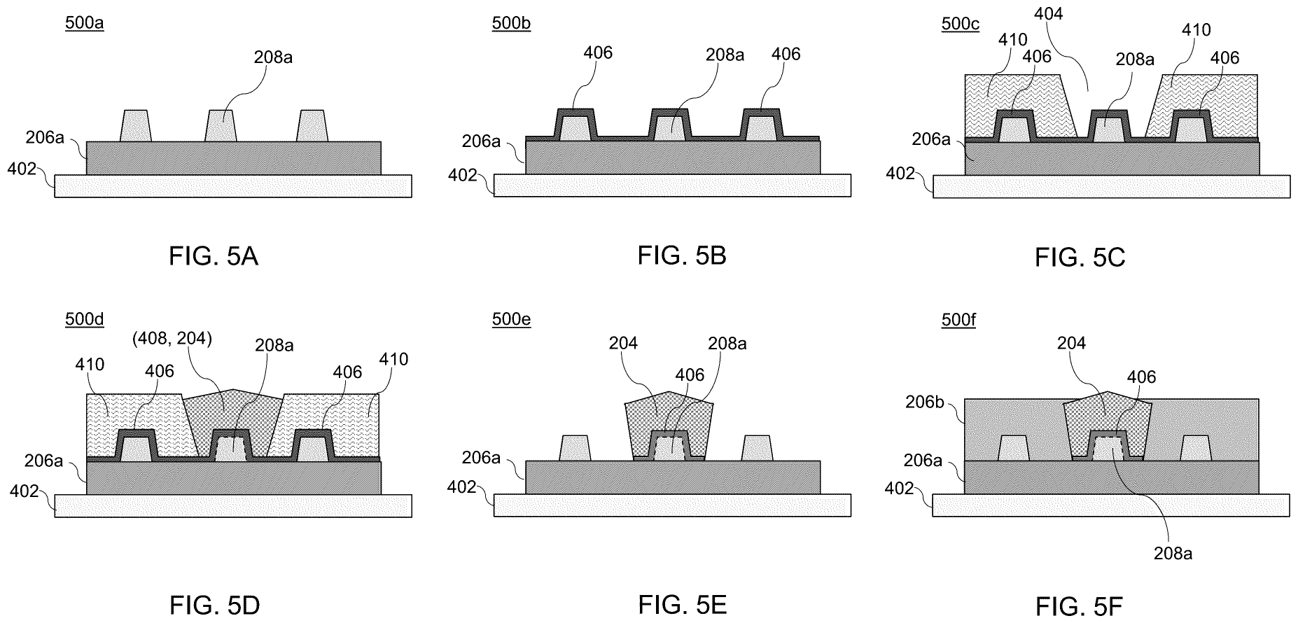

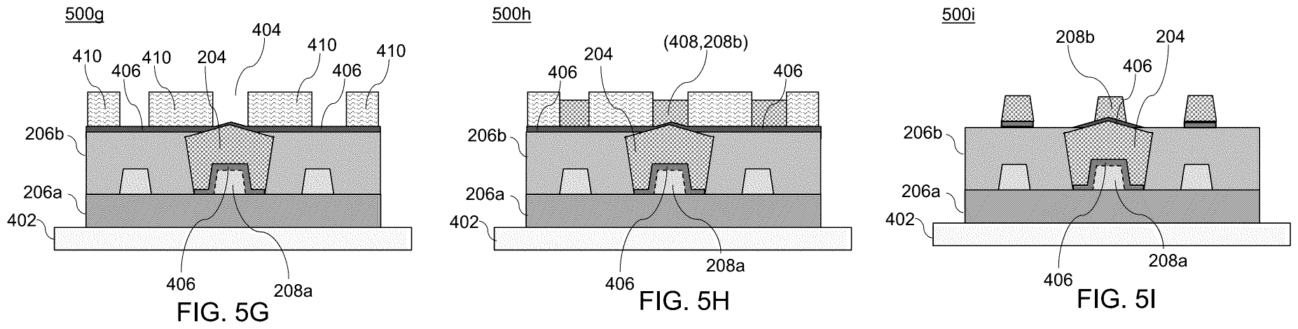

FIGS. 3A to 3F provide various views of a portion of a further embodiment interposer 108c having a increased interconnect density, according to various embodiments. In this regard, FIG. 3A is a first vertical cross-sectional view of the embodiment interposer 108c, FIG. 3B is a second vertical cross-sectional view of the embodiment interposer 108c of FIG. 3A, FIG. 3C is a top view of an electrical interconnect structure of the embodiment interposer 108c of FIG. 3A, FIG. 3D is a bottom view of the electrical interconnect structure of the embodiment interposer 108c of FIG. 3C, FIG. 3E is a three-dimensional top perspective view of the electrical interconnect structure of the embodiment interposer 108c of FIG. 3C, and FIG. 3F is a three-dimensional bottom perspective view of the electrical interconnect structure of the embodiment interposer 108c of the interposer of FIG. 3D, according to various embodiments. The embodiment interposer 108c of FIGS. 3A to 3F is similar to the embodiment interposer 108b described above with reference to FIG. 2. The embodiment interposer 108b of FIG. 2 and the embodiment interposer 108c of FIGS. 3A to 3F may be formed using methods described in greater detail with reference to FIGS. 4A to 5I, below.

As with the embodiment interposer 108b of FIG. 2, the embodiment interposer 108c of FIGS. 3A to 3F may include a first electrically conducting line structure 208a and an electrically conducting via structure 204 that is electrically connected to the first electrically conducting line structure 208a. A portion 302 (e.g., see FIGS. 3D and 3F) of the first electrically conducting line structure 208a may protrude (e.g., see FIG. 3A) into the electrically conducting via structure 204 such that the first electrically conducting line structure 208a is at least partially overlapping with the electrically conducting via structure 204. As shown in FIGS. 3A and 3B, the first electrically conducting line structure 208a and the electrically conducting via structure 204 may share a common surface 304. In this regard, the common surface 304 may be parallel to an interface between the first dielectric layer 206a and the second dielectric layer 206b. A first line thickness 218a of the first electrically conducting line structure 208a may be less than a via thickness 220 of the electrically conducting via structure 204 such that the first electrically conducting line structure 208a is at least partially overlapping with the electrically conducting via structure 204 along a thickness direction (i.e., along the z-direction in FIGS. 3A and 3B).

In the embodiment of FIGS. 3A to 3F, a combined spatial extent of the first electrically conducting line structure 208a and the electrically conducting via structure 204 along the thickness direction may equal the via thickness 220. As such, a vertical density of interconnect structures may be increased. Also, as shown in FIGS. 3A to 3F, a first line width 216a of the first electrically conducting line structure 208a may be less than a via width (214a, 214b) of the electrically conducting via structure 204 such that the first electrically conducting line structure 208a is at least partially overlapping with the electrically conducting via structure 204 along a width direction (i.e., along the x-direction and the y-direction in FIGS. 3A to 3F). As such, a combined spatial extent of the first electrically conducting line structure 208a and the electrically conducting via structure 204 along the width direction may be equal to the via width (214a, 214b). As described above, a portion 302 (e.g., see FIGS. 3D and 3F) of the first electrically conducting line structure 208a may be embedded within the via structure 204 (also see FIG. 3A) such that the first electrically conducting line structure 208a and the electrically conducting via structure 204 share a common connection volume.

The embodiment interposer 108c of FIGS. 3A to 3F) may further include a second electrically conducting line structure 208b electrically connected to the electrically conducting via structure 204 and formed on a side of the electrically conducting via structure 204 opposite to that of the first electrically conducting line structure 208a. For example, as shown in FIGS. 3A to 3F, the first electrically conducting line structure 208a may be formed on a bottom side, and the second electrically conducting line structure 208b may be formed on a top side of the electrically conducting via structure 204. The second electrically conducting line structure 208b may have a second line thickness 218b and may be formed in contact with a surface 306 of the electrically conducting via structure 204. As shown in FIG. 3A, the surface 306 of the electrically conducting via structure 204 may be perpendicular to the thickness direction (i.e., the z-direction) such that a combined spatial extent of the second electrically conducting line structure 208b and the electrically conducting via structure 204 along the thickness direction is greater than the via thickness and is given by a sum of the via thickness 220 and the second line thickness 218b.

FIG. 4A is vertical cross-sectional view of an intermediate structure 400a that may be used in the formation of an interposer (108b, 108c), according to various embodiments. The intermediate structure 400a may include a first dielectric layer 206a formed over a carrier substrate 402. Various interconnect structures may be formed over the first dielectric layer 206a, such as redistribution layer (RDL) interconnect structures. For example, the intermediate structure 400a may include a plurality of first electrically conducting line structures 208a. The intermediate structure 400a may be formed by depositing the first dielectric layer 206a over the carrier substrate 402 followed by forming the plurality of first electrically conducting line structures 208a.

The first dielectric layer 206a may include a dielectric polymer material such as polyimide (PI), benzocyclobutene (BCB), or polybenzobisoxazole (PBO) and may be formed by performing a spin coating process to deposit the first dielectric layer 206a. The deposited polymer material may then be dried to form the first dielectric layer 206a. A thickness of the first dielectric layer 206a may be in a range from 2 microns to 40 microns, such as from 4 microns to 20 microns. In other embodiments, the first dielectric layer 206a may include various other suitable polymers that may be deposited using other deposition methods.

The plurality of first electrically conducting line structures 208a may then be formed over the first dielectric layer 206a by depositing an electrically conductive seed layer (not shown) by sputtering, by applying and patterning a photoresist layer over the electrically conductive seed layer to form a pattern of openings through the photoresist layer, by electroplating a metallic fill material (such as copper, nickel, or a stack of copper and nickel), by removing the photoresist layer (for example, by ashing), and by etching portions of the electrically conductive seed layer located between the electroplated metallic fill material portions. The electrically conductive seed layer may include, for example, a stack of a titanium barrier layer and a copper seed layer. The titanium barrier layer may have thickness in a range from 50 nm to 300 nm, and the copper seed layer may have a thickness in a range from 100 nm to 500 nm. The metallic fill material for the plurality of first electrically conducting line structures 208a may include copper, nickel, or copper and nickel. The thickness of the metallic fill material that is deposited for the plurality of first electrically conducting line structures 208a may be in a range from 2 microns to 40 microns, such as from 4 microns to 10 microns, although larger or smaller thicknesses may also be used. In other alternative embodiments, a blanket layer of metallic fill material (not shown) may be deposited over the first dielectric layer 206a. A photoresist layer may be applied over the blanket layer of metallic fill material and patterned. Using the photoresist layer as an etch mask, the various electrically conducting line structures 208a may be formed through an etch process. The photoresist layer may be removed by, for example, ashing or dissolution.

FIG. 4B is vertical cross-sectional view of a further intermediate structure 400b that may be used in the formation of an interposer (108b, 108c), according to various embodiments. The intermediate structure 400b may be formed from the intermediate structure 400a by forming a second dielectric layer 206b over the intermediate structure 400a of FIG. 4A. The second dielectric layer 206b may include the same material as that of the first dielectric layer 206a. Alternatively, the second dielectric layer 206b may include a different material from that of the first dielectric layer 206a. In this regard, the second dielectric layer 206b may be a polymer material such as PI, BCM, or PBO, and may be formed by a process of spin coating. In other embodiments, the second dielectric layer 206b may include various other suitable polymers that may be deposited using other deposition methods.

FIG. 4C is vertical cross-sectional view of a further intermediate structure 400c that may be used in the formation of an interposer (108b, 108c), according to various embodiments. The intermediate structure 400c may be formed from the intermediate structure 400b by etching the second dielectric layer 206b to form openings 404 over respective ones of the plurality of first electrically conducting line structures 208a. In this regard, a patterned photoresist (not shown) may be formed over the second dielectric layer 206b. An etching process may then be performed to etch portions of the second dielectric layer 206b that are not masked by the patterned photoresist. As shown in FIG. 4C, an opening 404 may be formed by etching a region of the second dielectric layer 206b down to a surface of the first dielectric layer 206a. In this way, surfaces of the first electrically conducting line structure 208a may be exposed by the etching process that may be used to generate the opening 404.

FIG. 4D is vertical cross-sectional view of a further intermediate structure 400d that may be used in the formation of an interposer (108b, 108c), according to various embodiments. The intermediate structure 400d may be formed from the intermediate structure 400c by forming an electrically conductive seed layer 406 over the intermediate structure 400c of FIG. 4C. The electrically conductive seed layer 406 may be formed by sputtering and may include a metallic material such as copper, titanium, etc. For example, the electrically conductive seed layer 406 may be formed as a stack of a titanium barrier layer and a copper seed layer. The titanium barrier layer may have thickness in a range from 50 nm to 300 nm, and the copper seed layer may have a thickness in a range from 100 nm to 500 nm. Various other materials and thicknesses may be used for the electrically conductive seed layer 406 in other embodiments. The electrically conductive seed layer 406 may form an electrically conductive contact with the first electrically conducting line structure 208a.

FIG. 4E is vertical cross-sectional view of a further intermediate structure 400e that may be used in the formation of an interposer (108b, 108c), according to various embodiments. The intermediate structure 400e may be formed from the intermediate structure 400d by depositing an electrically conductive material 408 over the intermediate structure 400d of FIG. 4D. The electrically conductive material 408 may be a metallic fill material (such as copper, nickel, or a stack of copper and nickel) that may be deposited by performing an electroplating process. Other suitable metallic fill materials are within the contemplated scope of disclosure. The thickness of the metallic fill material that is deposited may be in a range from 2 microns to 40 microns, such as from 4 microns to 10 microns, although lesser or greater thicknesses may also be used. Various other electrically conducting materials and deposition methods may be used in other embodiments.

FIG. 4F is vertical cross-sectional view of a further intermediate structure 400f that may be used in the formation of an interposer (108b, 108c), according to various embodiments. The intermediate structure 400f may be formed from the intermediate structure 400e by forming a patterned photoresist 410 over the intermediate structure 400e of FIG. 4E. In this regard, a blanket layer of photoresist (not shown) may be deposited over a surface of the electrically conductive material 408 of the intermediate structure 400e. The blanket layer of photoresist may then be patterned using lithographic techniques to form the patterned photoresist 410. The patterned photoresist 410 may then be used during an anisotropic etch process that may be performed to etch the electrically conductive material 408, as described in greater detail with reference to FIG. 4G, below.

FIG. 4G is vertical cross-sectional view of a further intermediate structure 400g that may be used in the formation of an interposer (108b, 108c), according to various embodiments. The intermediate structure 400g may be formed from the intermediate structure 400f by performing an anisotropic etching process to etch the electrically conductive material 408. As shown, the etching process may be performed to remove unmasked portions of the electrically conductive material 408. As shown in FIG. 4G, the etching process may generate the electrically conducting via structure 204 along with the second electrically conducting line structure 208b. In this way, the electrically conducting via structure 204 may be formed along with the second electrically conducting line structure 208b as a monolithic structure. Further, as shown in in FIG. 4G, an electrically conductive connection may be formed between the electrically conducting via structure 204 and the first electrically conducting line structure 208a through the connection provided by the seed layer 406.

FIG. 4H is vertical cross-sectional view of a further intermediate structure 400h that may be used in the formation of an interposer (108b, 108c), according to various embodiments. The intermediate structure 400h may be formed from the intermediate structure 400g by removing the patterned photoresist 410 of the intermediate structure 400g of FIG. 4G. In this regard, the patterned photoresist 410 may be removed by ashing or by dissolution with a solvent. Additional interconnect layers may then be formed over the intermediate structure 400h by performing additional processing operations similar to those described above with reference to FIGS. 4A to 4G. For example, in an additional processing operation, a third dielectric layer 206c may be formed over the intermediate structure 400h to thereby form the portion of the interposers (108b, 108c) of FIGS. 2 to 3F. The resulting structure (e.g., see FIGS. 2, 3A, and 3B) may then be used as a starting point for the formation of additional interconnect layers using processes similar to those described above with reference to FIGS. 4A to 4H.

FIG. 5A is vertical cross-sectional view of an intermediate structure 500a that may be used in the formation of an interposer (108b, 108c), according to various embodiments. The intermediate structure 500a may be similar to the intermediate structure 400a. In this regard, the intermediate structure 500a may include a first dielectric layer 206a formed over a carrier substrate 402 and various interconnect structures formed over the first dielectric layer 206a, such as redistribution layer (RDL) interconnect structures. For example, the intermediate structure 500a may include a plurality of first electrically conducting line structures 208a. The intermediate structure 500a may be formed by depositing the first dielectric layer 206a over the carrier substrate 402 followed by forming the plurality of first electrically conducting line structures 208a. As with the intermediate structure 400a of FIG. 4A, the first dielectric layer 206a may include a dielectric polymer material such as PI, BCB, or PBO and may be formed by performing a spin coating process to deposit the first dielectric layer 206a.

The plurality of first electrically conducting line structures 208a may then be formed over the first dielectric layer 206a by depositing an electrically conductive seed layer (not shown) by sputtering, by applying and patterning a photoresist layer over the electrically conductive seed layer to form a pattern of openings through the photoresist layer, by electroplating a metallic fill material (such as copper, nickel, or a stack of copper and nickel), by removing the photoresist layer (for example, by ashing), and by etching portions of the electrically conductive seed layer located between the electroplated metallic fill material portions.

FIG. 5B is vertical cross-sectional view of a further intermediate structure 500a that may be used in the formation of an interposer (108b, 108c), according to various embodiments. The intermediate structure 500b may be formed from the intermediate structure 500a by forming an electrically conductive seed layer 406 over the intermediate structure 500a of FIG. 5A. The electrically conductive seed layer 406 may be formed by sputtering and may include a metallic material such as copper, titanium, etc. For example, the electrically conductive seed layer 406 may be formed as a stack of a titanium barrier layer and a copper seed layer. The titanium barrier layer may have thickness in a range from 50 nm to 300 nm, and the copper seed layer may have a thickness in a range from 100 nm to 500 nm. Various other materials and thicknesses may be used for the electrically conductive seed layer 406 in other embodiments. The electrically conductive seed layer 406 may form an electrically conductive contact with the first electrically conducting line structure 208a.

FIG. 5C is vertical cross-sectional view of a further intermediate structure 500c that may be used in the formation of an interposer (108b, 108c), according to various embodiments. The intermediate structure 500c may be formed from the intermediate structure 500b by forming a patterned photoresist 410 over the intermediate structure 500b of FIG. 5B. In this regard, a blanket layer of photoresist (not shown) may be deposited over a surface of the electrically conductive seed layer 406 of the intermediate structure 500b. The blanket layer of photoresist may then be patterned using lithographic techniques to form the patterned photoresist 410. As shown, the patterned photoresist 410 may include an opening 404 that exposes a portion of the electrically conductive seed layer 406 over the first electrically conducting line structure 208a. An electrically conductive material 408 may then be formed within the opening 404 of the patterned photoresist 410 as described in greater detail with reference to FIG. 5D, below.

FIG. 5D is vertical cross-sectional view of a further intermediate structure 500d that may be used in the formation of an interposer (108b, 108c), according to various embodiments. The intermediate structure 500d may be formed from the intermediate structure 500c by depositing an electrically conductive material 408 over the intermediate structure 400d of FIG. 4D. The electrically conductive material 408 may be a metallic fill material (such as copper, nickel, or a stack of copper and nickel) that may be deposited by performing an electroplating process. The thickness of the metallic fill material that is deposited may be in a range from 2 microns to 40 microns, such as from 4 microns to 10 microns, although lesser or greater thicknesses may also be used. Various other electrically conducting materials and deposition methods may be used in other embodiments.

FIG. 5E is vertical cross-sectional view of a further intermediate structure 500e that may be used in the formation of an interposer (108b, 108c), according to various embodiments. The intermediate structure 500e may be formed from the intermediate structure 500d by removing the patterned photoresist 410, for example, by ashing or by dissolution with a solvent. The resulting intermediate structure 500e includes the electrically conducting via structure 204 formed over the electrically conductive seed layer 406 and the first electrically conducting line structure 208a. As such, the electrically conductive seed layer 406 may form an electrically conductive contact between the first electrically conducting line structure 208a and the electrically conducting via structure 204. Additional interconnect structures may then be formed over the intermediate structure 500f as described with reference to FIGS. 5F to 5I, below.

FIG. 5F is vertical cross-sectional view of a further intermediate structure 500f that may be used in the formation of an interposer (108b, 108c), according to various embodiments. The intermediate structure 500f may be formed from the intermediate structure 500e by forming a second dielectric layer 206b over the intermediate structure 500e of FIG. 5E. The second dielectric layer 206b may include the same material as that of the first dielectric layer 206a. Alternatively, the second dielectric layer 206b may include a different material from that of the first dielectric layer 206a. In this regard, the second dielectric layer 206b may be a polymer material such as PI, BCM, or PBO, and may be formed by a process of spin coating. In other embodiments, the second dielectric layer 206b may include various other suitable polymers that may be deposited using other deposition methods.

FIG. 5G is vertical cross-sectional view of a further intermediate structure 500g that may be used in the formation of an interposer (108b, 108c), according to various embodiments. The intermediate structure 500g may be formed from the intermediate structure 500f by forming further electrically conductive seed layer 406 and a patterned photoresist 410 over the intermediate structure 500f of FIG. 5F. As shown, the electrically conductive seed layer 406 may be formed over a top surface of the intermediate structure 500f prior to formation of the patterned photoresist 410. The electrically conductive seed layer 406 may be formed by sputtering and may include a metallic material such as copper, titanium, etc., as described in greater detail above.

The patterned photoresist 410 may be formed using processes described above with reference to FIG. 4F. In this regard, a blanket layer of photoresist (not shown) may be deposited over a top surface of the intermediate structure 500f of FIG. 5F. The blanket layer of photoresist may then be patterned using lithographic techniques to form the patterned photoresist 410. As shown, the patterned photoresist 410 may include a plurality of openings 404 that expose portions of the electrically conductive seed layer 406 over the electrically conducting via structure 204 and over the second dielectric layer 206b. An electrically conductive material 408 may then be formed within the openings 404 of the patterned photoresist 410 as described in greater detail with reference to FIG. 5H, below.

FIG. 5H is vertical cross-sectional view of a further intermediate structure 500h that may be used in the formation of an interposer (108b, 108b), according to various embodiments. The intermediate structure 500h may be formed from the intermediate structure 500g by depositing an electrically conductive material 408 over the intermediate structure 500g of FIG. 5G. The electrically conductive material 408 may be a metallic fill material (such as copper, nickel, or a stack of copper and nickel) that may be deposited by performing an electroplating process. The thickness of the metallic fill material that is deposited may be in a range from 2 microns to 40 microns, such as from 4 microns to 10 microns, although lesser or greater thicknesses may also be used. Various other electrically conducting materials and deposition methods may be used in other embodiments.

FIG. 5I is vertical cross-sectional view of a further intermediate structure 500i that may be used in the formation of an interposer (108b, 108c), according to various embodiments. The intermediate structure 500i may be formed from the intermediate structure 500h by removing the patterned photoresist 410 of the intermediate structure 500h of FIG. 5H. In this regard, the patterned photoresist 410 may be removed by ashing or by dissolution with a solvent. As shown, remaining portions of the electrically conductive material 408 may form a plurality of second electrically conducting line structures 208b. In this way, the electrically conducting via structure 204 may and the electrically conducting via structure 204 may be electrically connect to one another through a connection provided by the seed layer 406.

Additional interconnect layers may then be formed over the intermediate structure 500i by performing additional processing operations similar to those described above with reference to FIGS. 5A to 5H. For example, in an additional processing operation, a third dielectric layer 206c may be formed over the intermediate structure 500i to thereby form the portion of the interposers (108b, 108c) of FIGS. 2 to 3F. The resulting structure (e.g., see FIGS. 2, 3A, and 3B) may then be used as a starting point for the formation of additional interconnect layers using processes similar to those described above with reference to FIGS. 5A to 5H.

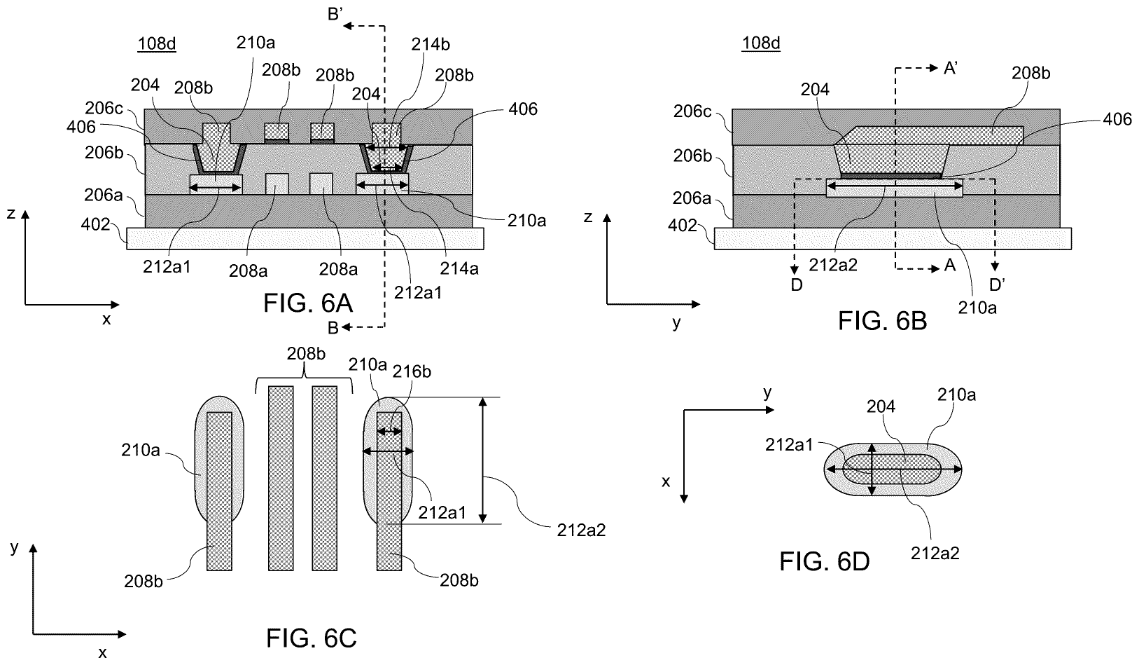

FIG. 6A is a first vertical cross-sectional view of a portion of a further interposer 108d having a increased interconnect density, and FIG. 6B is a second vertical cross-sectional view of the portion of the interposer of FIG. 6A, according to various embodiments. A first plane defining the cross-sectional view of FIG. 6B is indicated by the cross-section B-B′ in FIG. 6A and a second plane defining the cross-sectional view of FIG. 6A is indicated by the cross-section A-A′ in FIG. 6B. As with the interposers 108b and 108c of FIGS. 2 and 3A, respectively, the interposer 108d of FIGS. 6A and 6B may include a “line-on-via” structure in which a second electrically conducting line structure 208b may be formed along with an electrically conducting via structure 204 as a monolithic structure. In contrast to the interposers 108b and 108c of FIGS. 2 and 3A, however, the interposer 108d of FIGS. 6A and 6B include a via land 210a that may be electrically connected to the electrically conducting via structure 204 in place of the “line-in-via” structure of the interposers 108b and 108c. In this regard, the via land 210a may have an elongated structure (e.g., see FIGS. 6C and 6D) and may therefore have an increased contact area between the electrically conducting via structure 204 and the via land 210a. The increased contact area between the electrically conducting via structure 204 and the via land 210a may provide reduced electrical contact resistance relative to that of the interposers 108b and 108c of FIGS. 2 and 3A and, therefore, may be advantageous in certain embodiments.

FIG. 6C is a top view of electrical interconnect structures of the portion of the interposer 108d of FIG. 6A, and FIG. 6D is a horizontal cross-sectional view of the portion of the interposer 108d of FIG. 6A, according to various embodiments. The plane defining the cross-sectional view of FIG. 6D is indicated by the cross section D-D′ shown in FIG. 6B. As shown in FIGS. 6C and 6D, the via land 210a may have an reduced size (i.e., having a via land width 212a1) along a width direction (e.g., along the x-direction in FIGS. 6A, 6C, and 6D) and an elongated size (i.e., having a via land length 212a2) along a length direction (e.g., along the y-direction in FIGS. 6B, 6C, and 6D). As such, in the embodiment interposer 108d of FIGS. 6A to 6D, a horizontal density of electrical interconnect structures may be increased along the width direction. In this way, for certain embodiment applications, there may be a tradeoff between electrical contact resistance and electrical interconnect density. For example, the embodiment interposers 108b and 108c of FIGS. 2 and 3A may be more advantageous in applications requiring a greater density of interconnection structures, while the embodiment interposer 108d of FIGS. 6C and 6D may be more advantageous in applications in which lower electrical contrast resistance is a relatively more significant metric. As such, the choice among the various embodiment interposers (108b, 108c, 108d) may be dictated by circuit design considerations depending on respective applications.

As with the embodiment interposer of 108b and 108c of FIGS. 2 and 3A, respectively, the interposer 108d of FIGS. 6A and 6B may include a first dielectric layer 206a formed over a carrier substrate 402, a second dielectric layer 206b formed over the first dielectric layer 206a, and a third dielectric layer 206c formed over the second dielectric layer 206b. The interposer 108d of FIGS. 6A and 6B may further include a plurality of via land 210a structures and electrically conducting via structures 204 formed over the first dielectric layer 206a and within the second dielectric layer 206b. The electrically conducting via structures 204 may be separated from the via land 210a structures by an electrically conductive seed layer 406. As such, an electrically conductive connection may be formed between the electrically conducting via structure 204 and the via land 210a through the connection provided by the seed layer 406. As described above, the second electrically conducting line structure 208b may be formed along with the electrically conducting via structure 204 as a monolithic structure. In this regard, the electrically conducting via structure 204 may be formed within the second dielectric layer 206b and the second electrically conducting line structure 208b may be formed over the second dielectric layer 206b and within the third dielectric layer 206c.

As shown in FIG. 6C, the electrical interconnect structures of the interposer 108d may include a plurality of second electrically conducting line structures 208b. Also as shown in FIG. 6C, a subset of the plurality of second electrically conducting line structures 208b may be electrically and mechanically connected to via lands 210a. As described above, the via lands 210a may have an elongated structure with a land width 212a1 along a width direction (i.e., along the x-direction in FIGS. 6A, 6C, and 6D) and a land length 212a2 along a length direction (i.e., along the y-direction in FIGS. 6B, 6C, and 6D. Further, the land width 212a1 may be shorter than the land length 212a2. As shown in FIGS. 6C and 6D, the via land 210a may have a shape of an elongated oval structure. The via land 210a may have various other shapes (e.g., rectangular) in other embodiments. As described above, the elongated structure of the via land 210a may allow for a larger overlap area between the electrically conducting via structure 204 and the via land 210a leading to a reduced electrical contact resistance between the electrically conducting via structure 204 and the via land 210a. Further, a reduced land width 212a1 may provide an increased horizontal density of electrical interconnect structures along the width direction.

A smaller land width 212a1 may allow various electrical interconnect structures (e.g., second electrically conducting line structures 208b) to be placed closer to one another, while an increase in the land length 212a2 does not lead to an increase of the horizontal density of electrical interconnect structures because the longer dimension of the via land 210a (i.e., the land length 212a2) is aligned, and overlapping with, existing structures (i.e., second electrically conducting line structures 208b). As such, decreasing the size of the land width 212a1 leads to an increased density of electrical interconnect structures, while increasing the land length 212a2 leads to a reduced electrical contact resistance while avoiding an increased overall density of electrical interconnect structures.

The relative dimensions of various components of the interposer 108d may be similar to those of other embodiment interposers (108b, 108c) described above. In this regard, a via width (214a, 214b) of the electrically conducting via structure 204 may be less than the via land width 212a1 such that a combined spatial extent of the electrically conducting via structure 204 and the via land 210a along a width direction (i.e., along the x-direction in FIG. 2) is equal to the via land width 212a1. Similarly the second electrically conducting line structure 208b may have a second line width 216b (e.g., see FIG. 6C) that is less than the via land width 212a1 such that a combined spatial extent of the second electrically conducting line structure 208b and the via land 210a along the width direction may be equal to the via land width 212a1. Similarly, as shown in FIG. 6D, the electrically conducting via structure 204 may have a size and shape that are smaller than a corresponding size and shape of the via land 210a.

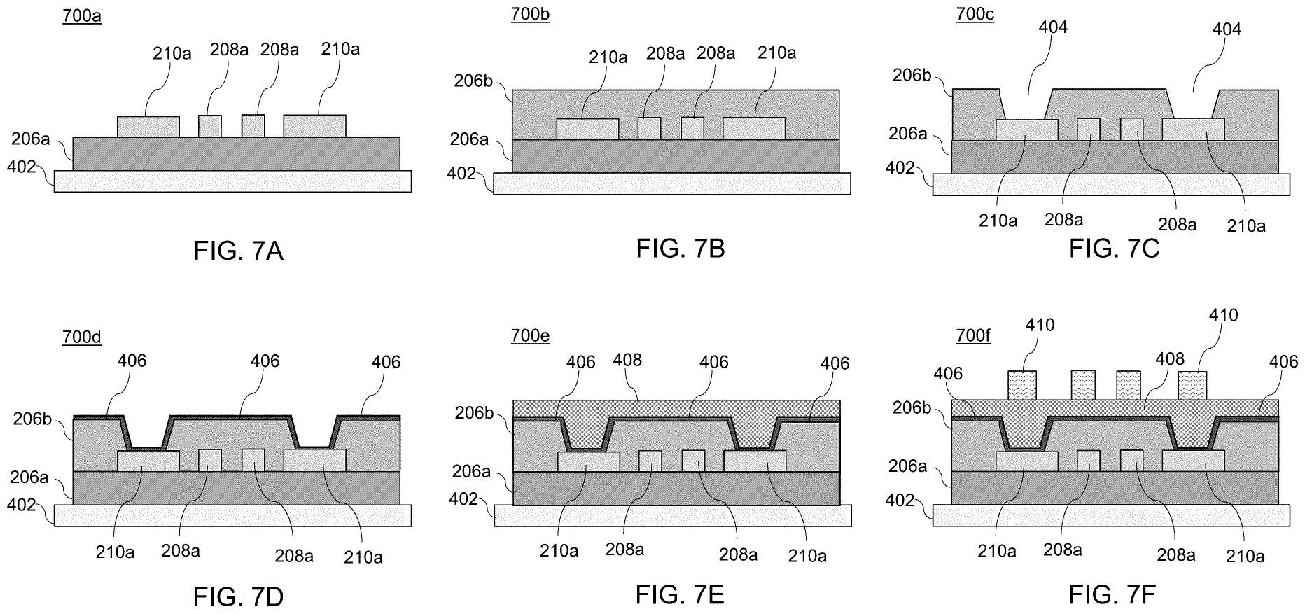

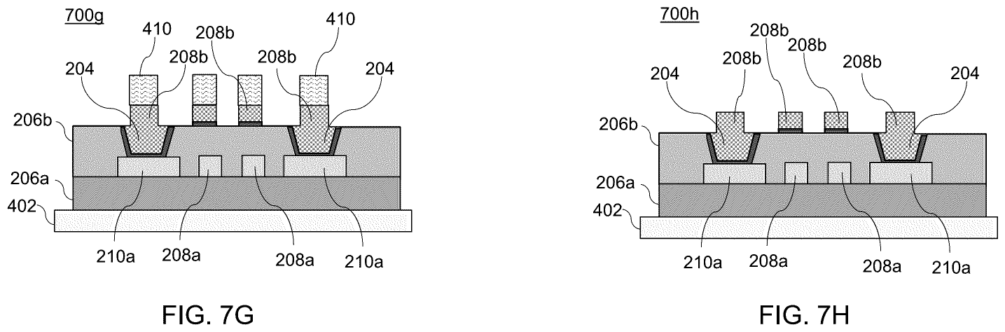

FIG. 7A is vertical cross-sectional view of an intermediate structure 700a that may be used in the formation of the further interposer 108d of FIGS. 6A and 6B, according to various embodiments. The intermediate structure 700a may be similar to the intermediate structures 400a and 500a. In this regard, the intermediate structure 700a may include a first dielectric layer 206a formed over a carrier substrate 402 and various electrical interconnect structures formed over the first dielectric layer 206a, such as redistribution layer (RDL) interconnect structures. For example, the intermediate structure 700a may include a plurality of first electrically conducting line structures 208a and via land 210a structures. The intermediate structure 700a may be formed by depositing the first dielectric layer 206a over the carrier substrate 402 followed by forming the plurality of first electrically conducting line structures 208a and via land 210a structures. As with the intermediate structures 400a and 500a of FIGS. 4A and 5A, respectively, the first dielectric layer 206a may include a dielectric polymer material such as PI, BCB, or PBO and may be formed by performing a spin coating process to deposit the first dielectric layer 206a. Other dielectric materials may be used in other embodiments and by be deposited by other deposition processes.

The plurality of first electrically conducting line structures 208a and via land 210a structures may then be formed over the first dielectric layer 206a by depositing an electrically conductive seed layer (not shown) by sputtering, by applying and patterning a photoresist layer over the electrically conductive seed layer to form a pattern of openings through the photoresist layer, by electroplating a metallic fill material (such as copper, nickel, or a stack of copper and nickel), by removing the photoresist layer (for example, by ashing), and by etching portions of the electrically conductive seed layer located between the electroplated metallic fill material portions.

FIG. 7B is vertical cross-sectional view of a further intermediate structure 700b that may be used in the formation of an interposer 108d, according to various embodiments. The intermediate structure 700b may be formed from the intermediate structure 700a by forming a second dielectric layer 206b over the intermediate structures 700a of FIG. 7A. The second dielectric layer 206b may include the same material as that of the first dielectric layer 206a. Alternatively, the second dielectric layer 206b may include a different material from that of the first dielectric layer 206a. In this regard, the second dielectric layer 206b may be a polymer material such as PI, BCM, or PBO, and may be formed by a process of spin coating. In other embodiments, the second dielectric layer 206b may include various other suitable polymers that may be deposited using other deposition methods.

FIG. 7C is vertical cross-sectional view of a further intermediate structure 700c that may be used in the formation of an interposer 108d, according to various embodiments. The intermediate structure 700c may be formed from the intermediate structure 700b by etching the second dielectric layer 206b to form openings 404 over respective ones of the plurality of via land structures 210a. In this regard, a patterned photoresist (not shown) may be formed over the second dielectric layer 206b. An etching process may then be performed to etch portions of the second dielectric layer 206b that are not masked by the patterned photoresist. As shown in FIG. 7C, openings 404 may be formed by etching regions of the second dielectric layer 206b down to a surface of the via land 210a. In this way, surfaces of the via land 210a structures may be exposed by the etching process that may be used to generate the opening 404.

FIG. 7D is vertical cross-sectional view of a further intermediate structure 700d that may be used in the formation of an interposer 108d, according to various embodiments. The intermediate structure 700d may be formed from the intermediate structure 700c by forming an electrically conductive seed layer 406 over the intermediate structure 700c of FIG. 7C. The electrically conductive seed layer 406 may be formed by sputtering and may include a metallic material such as copper, titanium, etc. For example, the electrically conductive seed layer 406 may be formed as a stack of a titanium barrier layer and a copper seed layer. The titanium barrier layer may have thickness in a range from 50 nm to 300 nm, and the copper seed layer may have a thickness in a range from 100 nm to 500 nm. Various other materials and thicknesses may be used for the electrically conductive seed layer 406 in other embodiments. The electrically conductive seed layer 406 may form an electrically conductive contact with the first via land 210a structures.

FIG. 7E is vertical cross-sectional view of a further intermediate structure 700e that may be used in the formation of an interposer 108d, according to various embodiments. The intermediate structure 700e may be formed from the intermediate structure 700d by depositing an electrically conductive material 408 over the intermediate structure 700d of FIG. 7D. The electrically conductive material 408 may be a metallic fill material (such as copper, nickel, or a stack of copper and nickel) that may be deposited by performing an electroplating process. The thickness of the metallic fill material that is deposited may be in a range from 2 microns to 40 microns, such as from 4 microns to 10 microns, although lesser or greater thicknesses may also be used. Various other electrically conducting materials and deposition methods may be used in other embodiments.

FIG. 7F is vertical cross-sectional view of a further intermediate structure 700f that may be used in the formation of an interposer 108d, according to various embodiments. The intermediate structure 700f may be formed from the intermediate structure 700e by forming a patterned photoresist 410 over the intermediate structure 700e of FIG. 7E. In this regard, a blanket layer of photoresist (not shown) may be deposited over a surface of the electrically conductive material 408 of the intermediate structure 700e. The blanket layer of photoresist may then be patterned using lithographic techniques to form the patterned photoresist 410. The patterned photoresist 410 may then be used during an anisotropic etch process that may be performed to etch the electrically conductive material 408, as described in greater detail with reference to FIG. 7G, below.

FIG. 7G is vertical cross-sectional view of a further intermediate structure 700g that may be used in the formation of an interposer 108d, according to various embodiments. The intermediate structure 700g may be formed from the intermediate structure 700f by performing an anisotropic etching process to etch the electrically conductive material 408. As shown, the etching process may be performed to remove unmasked portions of the electrically conductive material 408. As shown in FIG. 7G, the etching process may generate the electrically conducting via structures 204 along with the second electrically conducting line structures 208b. In this way, each electrically conducting via structure 204 may be formed along with a respective second electrically conducting line structure 208b as a monolithic structure. Further, as shown in in FIG. 7G, an electrically conductive connection may be formed between the electrically conducting via structure 204 and the via land 210a structure through the connection provided by the seed layer 406.

FIG. 7H is vertical cross-sectional view of a further intermediate structure 700h that may be used in the formation of an interposer 108d, according to various embodiments. The intermediate structure 700h may be formed from the intermediate structure 700g by removing the patterned photoresist 410 of the intermediate structure 700g of FIG. 7G. In this regard, the patterned photoresist 410 may be removed by ashing or by dissolution with a solvent. Additional interconnect layers may then be formed over the intermediate structure 700h by performing additional processing operations similar to those described above with reference to FIGS. 7A to 7G. For example, in an additional processing operation, a third dielectric layer 206c may be formed over the intermediate structure 700h to thereby form the portion of the interposer 108d of FIGS. 6A and 6B. The resulting structure (e.g., see FIGS. 6A and 6B) may then be used as a starting point for the formation of additional interconnect layers using processes similar to those described above with reference to FIGS. 7A to 7H.

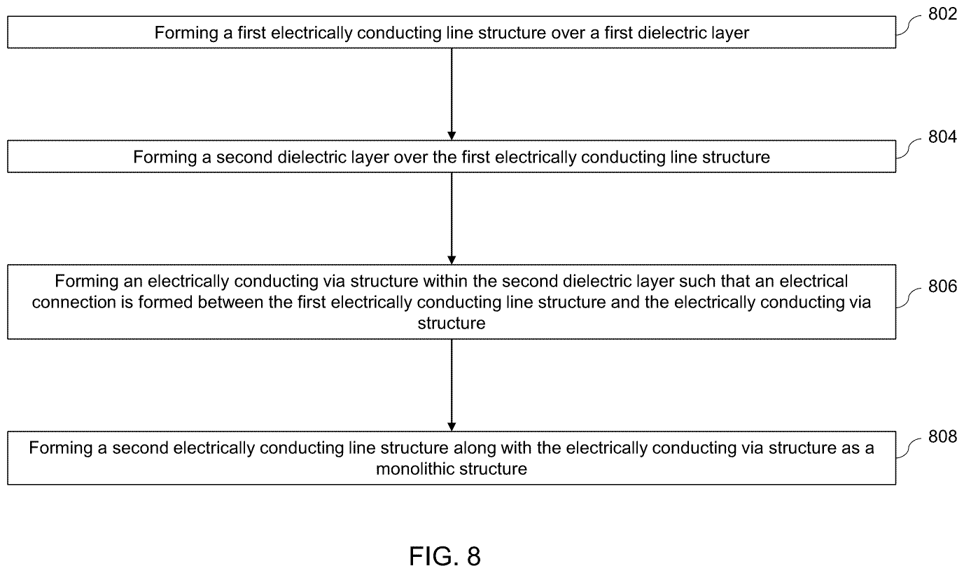

FIG. 8 is a flowchart of a method 800 of forming an interposer (108b, 108c), according to various embodiments. In operation 802, the method 800 may include forming a first electrically conducting line structure 208a over a first dielectric layer 206a. In operation 804, the method 800 may include forming a second dielectric layer 206b over the first electrically conducting line structure 208a. In operation 806, the method 800 may include forming an electrically conducting via structure 204 within the second dielectric layer 206b such that an electrical connection is formed between the first electrically conducting line structure 208a and the electrically conducting via structure 204. In operation 806, the method 800 may include forming a second electrically conducting line structure 208b along with the electrically conducting via structure 204 as a monolithic structure.

In forming the electrically conducting via structure 204 in operation 806, the method 800 may further include forming the electrically conducting via structure 204 over the first electrically conducting line structure 208a such that the electrically conducting via structure 204 is electrically connected to, and partially surrounds, a portion of the first electrically conducting line structure 208a. In this regard, the method 800 may further include performing operations including forming an electrically conductive seed layer 406 over the first electrically conducting line structure 208a and depositing an electrically conductive material 408 over the electrically conductive seed layer 406 such that the electrical connection is formed between the first electrically conducting line structure 208a, the electrically conductive seed layer 406, and the electrically conductive material 408. According to certain embodiments, method 800 may further include forming a via land 210a structure electrically connected to the first electrically conducting line structure 208a such that the via land 210a structure may include an elongated structure including a land width 212a1 that is smaller than a land length 212a2.

In forming the second electrically conducting line 208b structure over the electrically conducting via structure 204 in operation 808, the method 800 may further include performing one of a first set of operations (e.g., see FIGS. 4A to 4H) or a second set of operations (e.g., see FIGS. 5A to 5I). In this regard, according to some embodiments, the first set of operations may include forming a first patterned photoresist 410 over a surface of an electrically conductive material 408 that forms the electrically conducting via structure 204 and etching the electrically conductive material 408 to form the second electrically conducting line structure 208b. In other embodiments, the second set of operations may include forming a second patterned photoresist 410 over the second dielectric layer 206b such that an opening 404 of the second patterned photoresist 410 is located over the electrically conducting via structure 204 and depositing a second electrically conductive material 408 into the opening 404 of the second patterned photoresist 410 such that the second electrically conductive material 408 may form the second electrically conducting line structure 208b.

Referring to all drawings and according to various embodiments of the present disclosure, an interposer (108b, 108c, 108d) is provided. The interposer (108b, 108c, 108d) may include a first electrically conducting line structure 208a and an electrically conducting via structure 204 that is electrically connected to the first electrically conducting line structure 208a. The interposer (108b, 108c, 108d) may further include a second electrically conducting line structure 208b formed along with the electrically conducting via structure 204 as a monolithic structure.

In various embodiment interposers (108b, 108c), a portion 302 of the first electrically conducting line structure 208a may be provided within the electrically conducting via structure 204 such that the first electrically conducting line structure 208a is at least partially overlapping with the electrically conducting via structure 204. In various embodiments, the first electrically conducting line structure 208a and the electrically conducting via structure 204 may share a common surface 304. In various embodiments, a first line thickness 218a of the first electrically conducting line structure 208a may be less than a via thickness 220 of the electrically conducting via structure 204 such that the first electrically conducting line structure 208a is at least partially overlapping with the electrically conducting via structure 204 along a thickness direction (e.g., the z-direction). In certain embodiments, a combined spatial extent of the first electrically conducting line structure 208a and the electrically conducting via structure 204 along the thickness direction may equal the via thickness 220.

In still further embodiments, a first line width 216a of the first electrically conducting line structure 208a may be less than a via width (214a, 214b) of the electrically conducting via structure 204 such that the first electrically conducting line structure 208a is at least partially overlapping with the electrically conducting via structure 204 along a width direction. In other embodiments, a combined spatial extent of the first electrically conducting line structure 208a and the electrically conducting via structure 204 along the width direction may be equal to the via width (214a, 214b).

The first electrically conducting line structure 208a may be formed over a first dielectric layer 206a, a second dielectric layer 206b may be formed over the first dielectric layer 206a, and the electrically conducting via structure 204 may be formed within the second dielectric layer 206b over the portion 302 of the first electrically conducting line structure 208a so as to form an electrical connection with the first electrically conducting line structure 208a. The interposer (108b, 108c) may further include an electrically conductive seed layer 406 formed between the first electrically conducting line structure 208a and the electrically conducting via structure 204. The portion 302 of the first electrically conducting line structure 208a may be embedded within the electrically conducting via structure 204 such that the first electrically conducting line structure 208a and the electrically conducting via structure 204 share a common connection volume (e.g., see FIGS. 3A, 3D, and 3F).

In various embodiments, the second electrically conducting line structure 208b may include a second line thickness 218b and may be formed in contact with a surface 306 of the electrically conducting via structure 204. Further, the surface 306 of the electrically conducting via structure 204 may be perpendicular to a thickness direction (e.g., the z-direction) such that a first combined spatial extent of the second electrically conducting line structure 208b and the electrically conducting via structure 204 along the thickness direction is greater than the via thickness 220 (e.g., see FIGS. 2 and 3A). Further, in various embodiments, a second combined spatial extent of the second electrically conducting line structure 208b and the electrically conducting via structure 204 along the thickness direction may be given by a sum of the via thickness 220 and the second line thickness 218b (e.g., see FIGS. 2 and 3A).

According to various embodiments, an interposer (108b, 108c) may further include a via land 210a structure electrically connected to the first electrically conducting line structure 208a such that the via land 210a structure has an elongated structure including a land width 212a1 that is smaller than a land length 212a2. For example, the via land 210a structure may further have an elongated oval structure (e.g., see FIGS. 6C and 6D).

According to various embodiments, a further interposer (108b, 108c) is provided. The interposer (108b, 108c) may include a first dielectric layer 206a, a second dielectric layer 206b formed over the first dielectric layer 206a, a first electrically conducting line structure 208a formed over the first dielectric layer 206a and within the second dielectric layer 206b, and an electrically conducting via structure 204 formed within the second dielectric layer 206b and formed over the first electrically conducting line structure 208a such that the electrically conducting via structure 204 is electrically connected to, and partially surrounds, a portion 302 of the first electrically conducting line structure 208a.

According to other various embodiments, a further interposer (108b, 108c) is provided. The interposer (108b, 108c) may include a first dielectric layer 206a, a second dielectric layer 206b formed over the first dielectric layer 206a, a first electrically conducting line structure 208a formed over the first dielectric layer 206a and within the second dielectric layer 206b, and an electrically conducting via structure 204 formed within the second dielectric layer 206b. The interposer (108b, 108c) may further include a second electrically conducting line structure 208b formed along with the electrically conducting via structure 204 as a monolithic structure. In some embodiments, the electrically conducting via structure 204 may be formed within the second dielectric layer 206b and may be formed over the first electrically conducting line structure 208a such that the electrically conducting via structure 204 is electrically connected to, and partially surrounds, a portion of the first electrically conducting line structure 208a.

In various embodiments, a first line thickness 218a of the first electrically conducting line structure 208a may be less than a via thickness 220 of the electrically conducting via structure 204 such that a combined spatial extent of the first electrically conducting line structure 208a and the electrically conducting via structure 204 along a thickness direction is equal to the via thickness 220. A first line width 216a of the first electrically conducting line structure 208a may be less than a via width (214a, 214b) of the electrically conducting via structure 204 such that a combined spatial extent of the first electrically conducting line structure 208a and the electrically conducting via along a width direction is equal to the via width (214a, 214b). The interposer (108b, 108c) may further include a third dielectric layer 206c formed over the second dielectric layer 206b. In various embodiments, the second electrically conducting line structure 208b may be formed over the second dielectric layer 206b and within the third dielectric layer 206c such that the second electrically conducting line structure 208b is electrically connected to the electrically conducting via structure 204.

In further embodiments, the interposer (108b, 108c) may further include a via land 210a structure electrically connected to the first electrically conducting line structure 208a. Further, in some embodiments, the via land 210a structure may include an elongated structure having a land width 212a1 that is smaller than a land length 212a2.

The above-described embodiments may provide advantages over existing semiconductor package structures 100. In this regard, disclosed embodiments may simplify the formation of a semiconductor package structure 100 by providing an interposer (108b, 108c, 108d) that includes an increased interconnect density. In this regard, in certain embodiments, an interposer (108b, 108c) may include a first electrically conducting line structure 208a and an electrically conducting via structure 204 formed over the first electrically conducting line structure 208a such that the electrically conducting via structure 204 is electrically connected to, and partially surrounds, a portion 302 of the first electrically conducting line structure 208a. In this way, the portion 302 of the first electrically conducting line structure 208a may be protruding within the electrically conducting via structure 204 so as to overlap with the electrically conducting via structure 204. As such, a combined spatial extent of the first electrically conducting line structure 208a and the electrically conducting via structure 204 along a thickness direction (e.g., the z-direction in FIGS. 2 and 3A) may be less than the via thickness 220, and a combined spatial extent of the first electrically conducting line structure 208a and the electrically conducting via structure 204 along a width direction (e.g., the x-direction in FIGS. 2 and 3A) may be equal to the via width (214a, 214b). In this way, a vertical density and a horizontal density of interconnect structures may be increased.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An interposer, comprising:
a first electrically conducting line structure;
an electrically conducting via structure that is electrically connected to the first electrically conducting line structure; and
a second electrically conducting line structure formed along with the electrically conducting via structure as a monolithic structure.

2. The interposer of claim 1, wherein a portion of the first electrically conducting line structure is provided within the electrically conducting via structure such that the first electrically conducting line structure is at least partially overlapping with the electrically conducting via structure, and
wherein the first electrically conducting line structure and the electrically conducting via structure share a common surface.

3. The interposer of claim 2, wherein a first line thickness of the first electrically conducting line structure is less than a via thickness of the electrically conducting via structure such that the first electrically conducting line structure is at least partially overlapping with the electrically conducting via structure along a thickness direction.

4. The interposer of claim 3, wherein a combined spatial extent of the first electrically conducting line structure and the electrically conducting via structure along the thickness direction equals the via thickness.

5. The interposer of claim 2, wherein a first line width of the first electrically conducting line structure is less than a via width of the electrically conducting via structure such that the first electrically conducting line structure is at least partially overlapping with the electrically conducting via structure along a width direction.

6. The interposer of claim 5, wherein a combined spatial extent of the first electrically conducting line structure and the electrically conducting via structure along the width direction is equal to the via width.

7. The interposer of claim 1, wherein:
the first electrically conducting line structure is formed over a first dielectric layer;
a second dielectric layer is formed over the first dielectric layer; and
the electrically conducting via structure is formed within the second dielectric layer over a portion of the first electrically conducting line structure so as to form an electrical connection with the first electrically conducting line structure.

8. The interposer of claim 1, further comprising an electrically conductive seed layer formed between the first electrically conducting line structure and the electrically conducting via structure.

9. The interposer of claim 1, wherein a portion of the first electrically conducting line structure is embedded within the electrically conducting via structure such that the first electrically conducting line structure and the electrically conducting via structure share a common connection volume.

10. The interposer of claim 1, wherein:
the second electrically conducting line structure comprises a second line thickness and is formed in contact with a surface of the electrically conducting via structure;
the surface of the electrically conducting via structure is perpendicular to a thickness direction such that a first combined spatial extent of the second electrically conducting line structure and the electrically conducting via structure along the thickness direction is greater than the via thickness; and
wherein a second combined spatial extent of the second electrically conducting line structure and the electrically conducting via structure along the thickness direction is given by a sum of the via thickness and the second line thickness.

11. The interposer of claim 1, further comprising:
a via land structure electrically connected to the first electrically conducting line structure,
wherein the via land structure comprises an elongated structure comprising a land width that is smaller than a land length.

12. The interposer of claim 11, wherein the via land structure further comprises an elongated oval structure.

13. An interposer, comprising:
a first dielectric layer;
a second dielectric layer formed over the first dielectric layer;
a first electrically conducting line structure formed over the first dielectric layer and within the second dielectric layer;
an electrically conducting via structure formed within the second dielectric layer; and
a second electrically conducting line structure formed along with the electrically conducting via structure as a monolithic structure.

14. The interposer of claim 13, wherein the electrically conducting via structure is formed within the second dielectric layer and formed over the first electrically conducting line structure such that the electrically conducting via structure is electrically connected to, and partially surrounds, a portion of the first electrically conducting line structure, and
wherein a first line thickness of the first electrically conducting line structure is less than a via thickness of the electrically conducting via structure such that a combined spatial extent of the first electrically conducting line structure and the electrically conducting via structure along a thickness direction is equal to the via thickness.

15. The interposer of claim 13, further comprising:
a third dielectric layer formed over the second dielectric layer,
wherein the second electrically conducting line structure is formed over the second dielectric layer and within the third dielectric layer such that the second electrically conducting line structure is electrically connected to the electrically conducting via structure.

16. The interposer of claim 13, further comprising:
a via land structure electrically connected to the first electrically conducting line structure,
wherein the via land structure comprises an elongated structure comprising a land width that is smaller than a land length.

17. A method forming an interposer, comprising:
forming a first electrically conducting line structure over a first dielectric layer;
forming a second dielectric layer over the first electrically conducting line structure;
forming an electrically conducting via structure within the second dielectric layer such that an electrical connection is formed between the first electrically conducting line structure and the electrically conducting via structure; and
forming a second electrically conducting line structure along with the electrically conducting via structure as a monolithic structure.

18. The method of claim 17, wherein forming the electrically conducting via structure further comprises forming the electrically conducting via structure over the first electrically conducting line structure such that the electrically conducting via structure is electrically connected to, and partially surrounds, a portion of the first electrically conducting line structure, by performing operations comprising:
forming an electrically conductive seed layer over the first electrically conducting line structure; and
depositing an electrically conductive material over the electrically conductive seed layer such that the electrical connection is formed between the first electrically conducting line structure, the electrically conductive seed layer, and the electrically conductive material.

19. The method of claim 17, further comprising:
forming a via land structure electrically connected to the first electrically conducting line structure,
wherein the via land structure comprises an elongated structure comprising a land width that is smaller than a land length.

20. The method of claim 17, wherein forming the second electrically conducting line structure over the electrically conducting via structure further comprises performing one of a first set of operations or a second set of operations, wherein the first set of operations comprises:
forming a first patterned photoresist over a surface of an electrically conductive material forming the electrically conducting via structure; and
etching the electrically conductive material to form the second electrically conducting line structure, and
wherein the second set of operations comprises:
forming a second patterned photoresist over the second dielectric layer such that an opening of the second patterned photoresist is located over the electrically conducting via structure; and
depositing a second electrically conductive material into the opening of the second patterned photoresist such that the second electrically conductive material comprises the second electrically conducting line structure.
